(19) United States
(12) Patent Application Publication
(10) Pub. No.: US 2026/0304853 A1
(43) Pub. Date: Oct. 1, 2026

(54) POWER SEMICONDUCTOR DEVICE, POWER CONVERSION DEVICE, AND METHOD OF MANUFACTURING POWER SEMICONDUCTOR DEVICE

(71) Applicant: Mitsubishi Electric Corporation, Chiyoda-ku, Tokyo (JP)

(72) Inventors: Yoshitaka KIMURA, Tokyo (JP); Munenori IKEDA, Tokyo (JP); Kazunari NAKATA, Tokyo (JP); Keiji BEPPU, Tokyo (JP); Masaya NONOMURA, Tokyo (JP); Fumitoshi YAMAMOTO, Tokyo (JP); Michiaki TAKENAKA, Tokyo (JP)

(73) Assignee: Mitsubishi Electric Corporation, Chiyoda-ku, Tokyo (JP)

(21) Appl. No.: 19/479,179

(22) PCT Filed: May 27, 2024
(86) PCT No.: PCT/JP2024/019353

§ 371 Date: Oct. 27, 2025

(30) Foreign Application Priority Data
May 29, 2023 (JP) 2023-087534

(51) Int. Cl. H10D 62/10; H02M 7/5387; H10D 30/01; H10D 30/66; H10D 62/60; H10D 62/832; H10D 64/27

(52) U.S. Cl. CPC H10D 62/102; H02M 7/5387; H10D 30/0297; H10D 30/668; H10D 62/124; H10D 62/60; H10D 62/8325; H10D 64/514; H10D 64/518

(57) ABSTRACT

The present disclosure has an object of suppressing destruction of a chip in a trench-gate power semiconductor device. A SiC-MOSFET includes: a bottom base region in a part of a drift layer that is in contact with a bottom of a trench; a sidewall base region in a part of the drift layer that is in contact with a second sidewall of the trench; a gate electrode 8 inside the trench; a source electrode in contact with a source region; and a drain electrode on a second main surface of a SiC substrate, wherein an angle β between the bottom of the trench and a first sidewall is larger than an angle γ between the bottom of the trench and the second sidewall, and the angle γ is less than 90°.

### TECHNICAL FIELD

The present disclosure relates to a power semiconductor device.

### BACKGROUND ART

Semiconductor devices using silicon carbide (SiC) substrates (hereinafter referred to as “SiC semiconductor devices”) are superior in breakdown voltage and heat resistance to semiconductor devices using silicon (Si) substrates (hereinafter referred to as “Si semiconductor devices”). Conventionally, the SiC semiconductor devices have found applications in power semiconductor devices such as a metal-oxide-semiconductor field effect transistor (MOSFET) and an insulated-gate bipolar transistor (IGBT) so that, for example, the semiconductor devices can increase the breakdown voltage, reduce losses, and be used under high-temperature environments.

Since SiC has a dielectric breakdown field strength higher than that of Si, in the SiC semiconductor devices, drift layers that are breakdown voltage layers for implementing breakdown voltages identical to those of Si semiconductor devices can be made thinner than those of the Si semiconductor devices. Furthermore, the SiC semiconductor devices can increase impurity doping amounts of the breakdown voltage layers more than those of the Si semiconductor devices. For these reasons, the SiC semiconductor devices obtain ON resistances significantly smaller than those of the Si semiconductor devices. For example, a SiC-MOSFET whose breakdown voltage is 1 kV or higher and 1.2 kV or lower has a ON resistance of 5 mΩ cm² or lower, which is a value less than or equal to half of that of a Si-MOSFET or an Si-IGBT with the same breakdown voltage.

From now on, it is expected that most of Si-IGBTs as inverter components will be replaced with the SiC semiconductor devices along with improvement in the manufacturing cost, the process technology, and other performances. Currently, trench-gate SiC-MOSFETs or SiC-IGBTs have been developed to reduce losses in conducting currents through the SiC semiconductor devices.

The trench-gate SiC-MOSFETs or SiC-IGBTs, however, have a problem in that an electric field and a current concentrate on corners of a bottom of a trench in a cell region, and a problem on destruction of chips.

### PRIOR ART DOCUMENT

### Patent Document

[Patent Document 1] Japanese Patent Application Laid-Open No. H9-275212

### SUMMARY

### Problem to Be solved by the invention

Patent Document 1 discloses a technology for suppressing the concentration of an electric field and a current on a trench gate electrode in a chip periphery and suppressing the destruction of a chip, with a structure for preventing the trench gate electrode in the chip periphery from performing a MOS operation when a gate voltage is applied to the trench gate electrode. In the structure of Patent Document 1, however, an electric field and a current concentrate on a bottom of a trench gate electrode except that in the chip periphery. Thus, a problem of destruction of a chip occurs.

The present disclosure has been conceived to solve the aforementioned problems, and has an object of suppressing destruction of a chip in a trench-gate power semiconductor device.

### Means to Solve the Problem

A power semiconductor device according to the present disclosure includes: a SiC substrate; a drift layer of a first conductivity type, the drift layer being formed on a first main surface of the SiC substrate; a base region of a second conductivity type, the base region being formed in a surface layer of the drift layer; an impurity region of the first conductivity type, the impurity region being partially formed in a surface layer of the base region; a trench penetrating the impurity region and the base region from a surface of the impurity region to reach an interior of the drift layer, the trench including a first sidewall and a second sidewall which face each other; a bottom base region of the second conductivity type, the bottom base region being formed in a part of the drift layer, the part being in contact with a bottom of the trench; a sidewall base region of the second conductivity type, the sidewall base region being formed in a part of the drift layer, the part being in contact with the second sidewall of the trench; a gate electrode formed inside the trench through a gate insulating film; a surface electrode in contact with the impurity region; and a back electrode formed on a second main surface that is a main surface opposite to the first main surface of the SiC substrate, wherein an angle between the bottom of the trench and the first sidewall is larger than an angle between the bottom of the trench and the second sidewall, and the angle between the bottom of the trench and the second sidewall is less than 90°.

### Effects of the Invention

In a power semiconductor device according to the present disclosure, a bottom base region limits current paths to a first sidewall side of a trench. Since an angle between a bottom of the trench and the first sidewall is larger than an angle between the bottom of the trench and a second sidewall, an electric field at an end of the bottom of the trench which is in contact with the first sidewall is smaller than an electric field at an end of the bottom of the trench which is in contact with the second sidewall. Thus, reducing the electric field at the end of the bottom of the trench which functions as current paths results in avoidance of concentration of both of a current and the electric field at the end of the bottom of the trench, and suppresses destruction of a chip.

### BRIEF DESCRIPTION OF DRAWINGS

FIG. 1 is a cross-sectional view of a SiC-MOSFET according to Embodiment 1.

FIG. 2 is a flowchart illustrating a method of manufacturing the SiC-MOSFET according to Embodiment 1.

FIG. 3 is a cross-sectional view illustrating a step of manufacturing the SiC-MOSFET according to Embodiment 1.

FIG. 4 is a cross-sectional view illustrating a step of manufacturing the SiC-MOSFET according to Embodiment 1.

FIG. 5 is a cross-sectional view illustrating a step of manufacturing the SiC-MOSFET according to Embodiment 1.

FIG. 6 is a cross-sectional view illustrating a step of manufacturing the SiC-MOSFET according to Embodiment 1.

FIG. 7 is a cross-sectional view illustrating a step of manufacturing the SiC-MOSFET according to Embodiment 1.

FIG. 8 is a cross-sectional view illustrating a step of manufacturing the SiC-MOSFET according to embodiment 1.

FIG. 9 is a cross-sectional view illustrating a step of manufacturing the SiC-MOSFET according to Embodiment 1.

FIG. 10 is a cross-sectional view illustrating a step of manufacturing the SiC-MOSFET according to Embodiment 1.

FIG. 11 is a cross-sectional view illustrating a step of manufacturing the SiC-MOSFET according to Embodiment 1.

FIG. 12 is a cross-sectional view illustrating a step of manufacturing the SiC-MOSFET according to Embodiment 1.

FIG. 13 is a cross-sectional view illustrating a step of manufacturing the SiC-MOSFET according to Embodiment 1.

FIG. 14 is a cross-sectional view illustrating a step of manufacturing the SiC-MOSFET according to Embodiment 1.

FIG. 15 is a cross-sectional view illustrating a step of manufacturing the SiC-MOSFET according to Embodiment 1.

FIG. 16 is a cross-sectional view illustrating a step of manufacturing the SiC-MOSFET according to Embodiment 1.

FIG. 17 is a cross-sectional view illustrating a step of manufacturing the SiC-MOSFET according to Embodiment 1.

FIG. 18 is a cross-sectional view illustrating current paths in the SiC-MOSFET according to Embodiment 1.

FIG. 19 is a cross-sectional view illustrating an electric field occurring in a corner of a bottom of a trench in the SiC-MOSFET according to Embodiment 1.

FIG. 20 is a cross-sectional view illustrating an electric field occurring in a corner of the bottom of the trench in the SiC-MOSFET according to Embodiment 1.

FIG. 21 is a cross-sectional view of a SiC-MOSFET according to Embodiment 2.

FIG. 22 is a cross-sectional view illustrating a step of manufacturing the SiC-MOSFET according to Embodiment 2.

FIG. 23 is a cross-sectional view illustrating a step of manufacturing the SiC-MOSFET according to Embodiment 2.

FIG. 24 is a cross-sectional view illustrating a step of manufacturing the SiC-MOSFET according to Embodiment 2.

FIG. 25 is a cross-sectional view of a SiC-MOSFET according to Embodiment 3.

FIG. 26 is a cross-sectional view illustrating a step of manufacturing the SiC-MOSFET according to Embodiment 3.

FIG. 27 is a cross-sectional view illustrating a step of manufacturing the SiC-MOSFET according to Embodiment 3.

FIG. 28 is a diagram illustrating a distribution of p-type ion concentration at the bottom of the trench in the SiC-MOSFET according to Embodiment 3.

FIG. 29 is a cross-sectional view illustrating a step of manufacturing the SiC-MOSFET according to Embodiment 3.

FIG. 30 is a cross-sectional view of a SiC-MOSFET according to Embodiment 4.

FIG. 31 is a cross-sectional view illustrating a step of manufacturing the SiC-MOSFET according to Embodiment 4.

FIG. 32 is a block diagram illustrating a configuration of a power conversion system to which the power semiconductor devices according to Embodiments 1, 2, 3, and 4 are applied.

### DESCRIPTION OF EMBODIMENTS

### A. Embodiment 1

### A-1. Structure

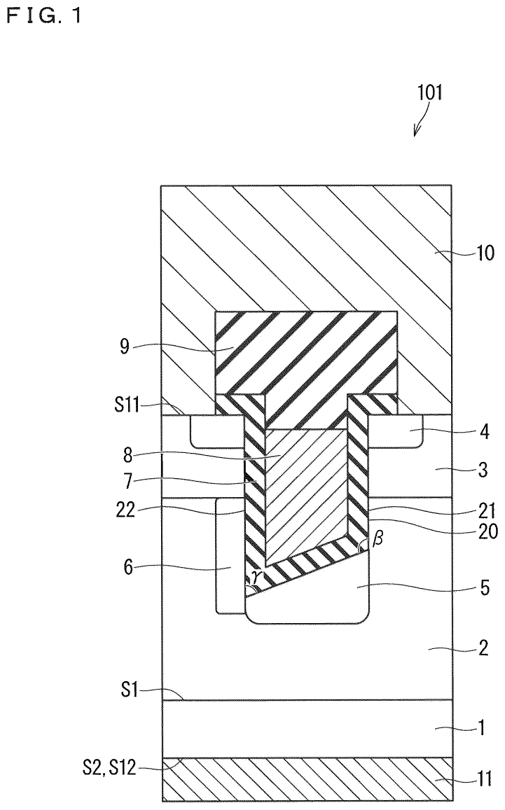

FIG. 1 is a cross-sectional view of a SiC-MOSFET 101 that is a power semiconductor device according to Embodiment 1. The SiC-MOSFET 101 includes an n-type SiC substrate 1, an n-type drift layer 2, a p-type base region 3, an n-type source region 4, a trench 20, a p-type bottom base region 5, a p-type sidewall base region 6, a gate insulating film 7, a gate electrode 8, an interlayer insulating film 9, a source electrode 10, and a drain electrode 11.

The SiC substrate 1 has a first main surface S1, and a second main surface S2 that is a main surface opposite to the first main surface S1. The drift layer 2 is made of n-type SiC, and is provided on the first main surface S1 of the SiC substrate 1. A combination of the SiC substrate 1, the drift layer 2, and an impurity region to be formed in a surface layer of the drift layer 2 to be described later will be referred to as a semiconductor substrate 50. The semiconductor substrate 50 has a first main surface S11, and a second main surface S12 that is a main surface opposite to the first main surface S11. The second main surface S12 matches the second main surface S2 of the SiC substrate 1.

The base region 3 is provided in the surface layer of the drift layer 2. The source region 4 that is the impurity region of the first conductivity type is partially provided in a surface layer of the base region 3. An upper surface of the source region 4 and an upper surface of the base region 3 in a region in which the source region 4 is not formed make up the first main surface S11 of the semiconductor substrate 50.

The trench 20 penetrates the source region 4 and the base region 3 from the first main surface S11 in the thickness direction to reach the drift layer 2. The bottom base region 5 is provided in a part of the drift layer 2 which is in contact with the bottom of the trench 20. The trench 20 includes a first sidewall 21 and a second sidewall 22 which face each other. While the sidewall base region 6 is provided in a part of the drift layer 2 which is in contact with the second sidewall 22 of the trench 20, the sidewall base region 6 is not provided in a part of the drift layer 2 which is in contact with the first sidewall 21.

The bottom of the trench 20, that is, the upper surface of the bottom base region 5 has an inclination with respect to the first main surface S1 of the SiC substrate 1. Here, an angle between the bottom of the trench 20 and the first sidewall 21 is defined as a first angle β, and an angle between the bottom of the trench 20 and the second sidewall 22 is defined as a second angle γ. The first angle β is larger than the second angle γ at the bottom of the trench 20. Furthermore, the second angle γ is less than 90°.

The gate insulating film 7 is provided at the bottom and along the sidewall of the trench 20, and on a partial region of the source region 4. The gate electrode 8 is provided in the trench 20 through the gate insulating film 7. The interlayer insulating film 9 is formed on the gate electrode 8 and on the gate insulating film 7 formed on the source region 4.

The source electrode 10 that is a surface electrode is provided on the first main surface S11 of the semiconductor substrate 50 and on the interlayer insulating film 9, and is in contact with the source region 4. The drain electrode 11 that is a back electrode is provided on the second main surface S2 of the SiC substrate 1.

### A-2. Manufacturing Method

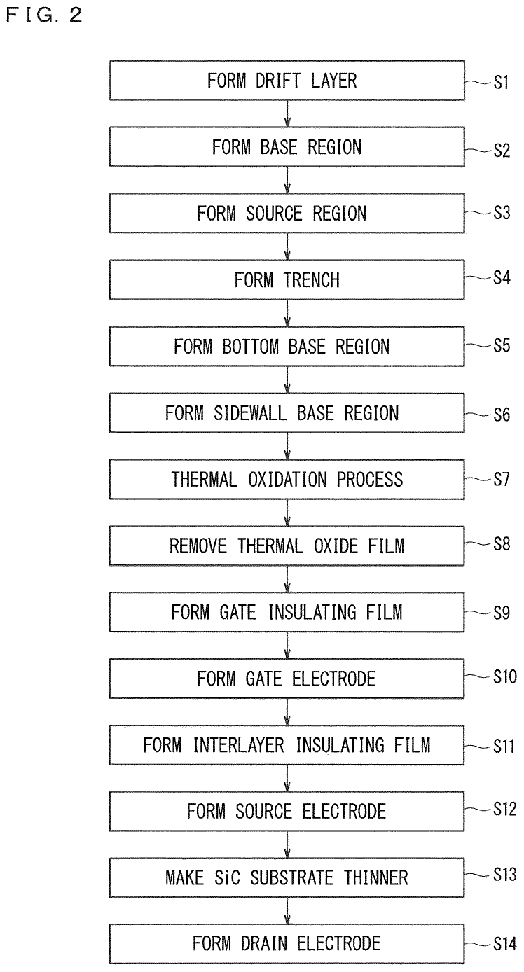

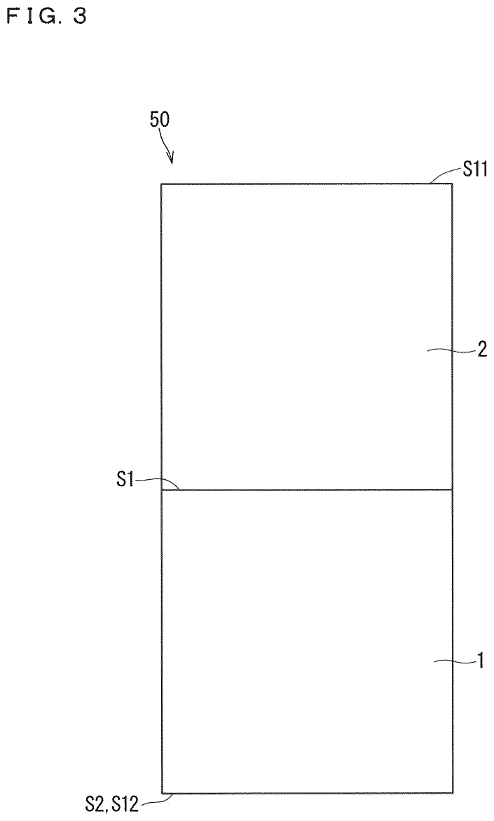

FIG. 2 is a flowchart illustrating a method of manufacturing the SiC-MOSFET 101. FIGS. 3 to 17 are cross-sectional views of the SiC-MOSFET 101 being manufactured. The method of manufacturing the SiC-MOSFET 101 will be described with reference to these drawings.

First, the drift layer 2 made of n-type SiC is formed on the first main surface S1 of the SiC substrate 1 as an epitaxial film (Step S1). This results in the semiconductor substrate 50 including the SiC substrate 1 and the drift layer 2 as illustrated in FIG. 3. An upper surface and a lower surface of the semiconductor substrate 50 in FIG. 3 will be referred to as the first main surface S11 and the second main surface S12, respectively.

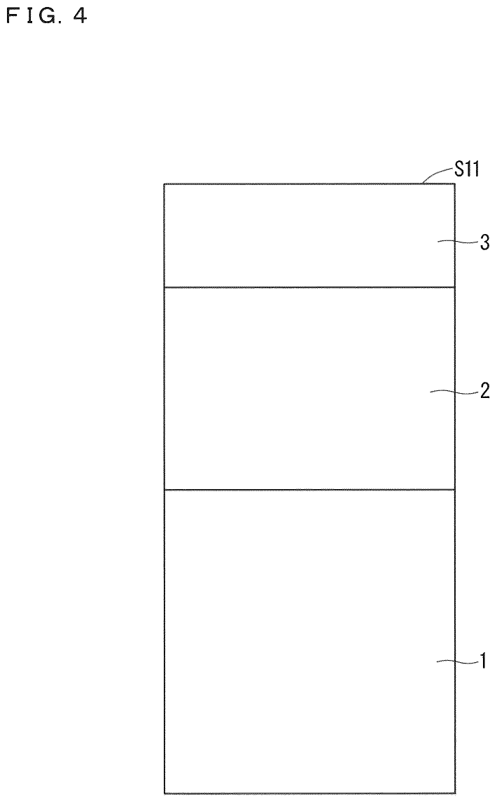

Next, a mask (not illustrated) is formed on the drift layer 2 using, for example, a resist, and the p-type base region 3 is formed in the surface layer of the drift layer 2 by ion-implanting impurities using this mask (Step S2). FIG. 4 illustrates this state. Examples of p-type impurities for forming the base region 3 include boron (B) and aluminum (Al).

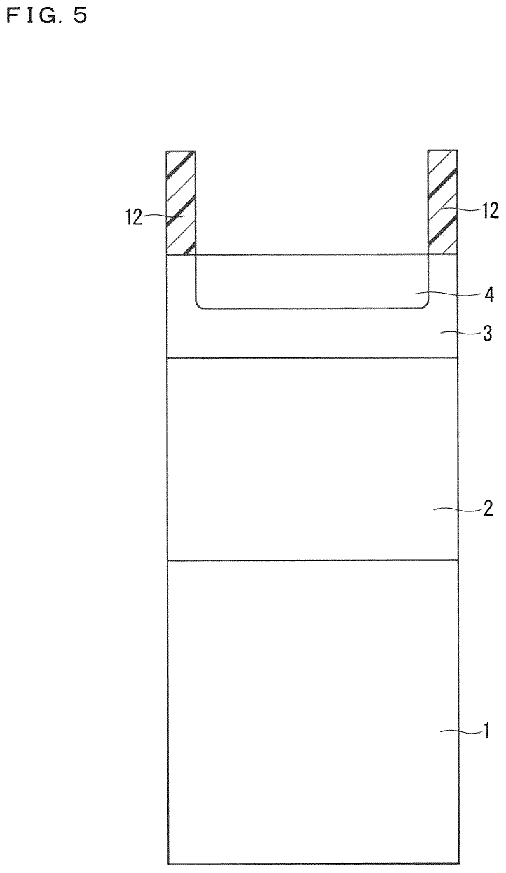

Then, a resist mask 12 is formed on the base region 3, and the n-type source region 4 is formed in the surface layer of the base region 3 by ion-implanting impurities using the resist mask 12 (Step S3). FIG. 5 illustrates this state. Examples of n-type impurities for forming the source region 4 include phosphorus (P) and nitrogen (N).

Then, the semiconductor substrate 50 is subjected to a heat treatment at high temperatures by a heat treatment apparatus (not illustrated) to electrically activate p-type ions implanted into the base region 3 and n-type ions implanted into the source region 4.

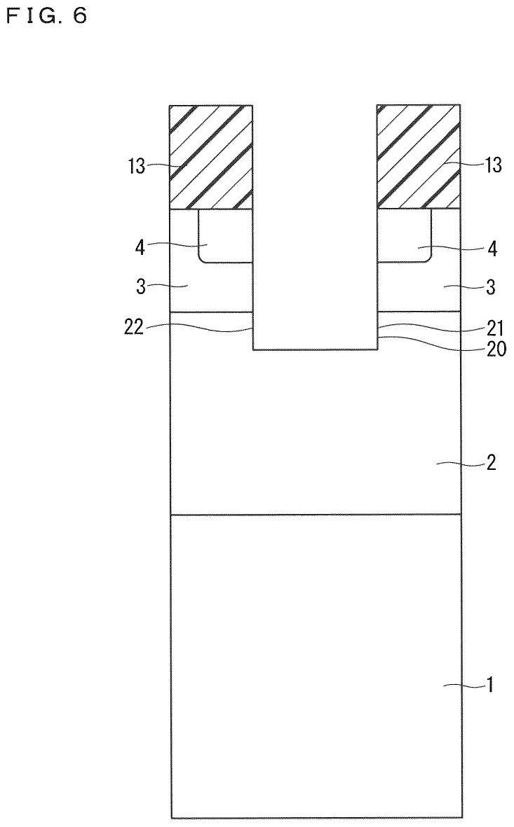

Next, the resist mask 12 is removed to form another resist mask 13 on the first main surface S11. Then, the trench 20 is formed by, for example, plasma dry etching using the resist mask 13 (Step S4). FIG. 6 illustrates this state. The trench 20 penetrates the source region 4 and the base region 3 from the first main surface S11 to reach the drift layer 2. In FIG. 6, a right sidewall of the trench 20 is the first sidewall 21, and a left sidewall of the trench 20 is the second sidewall 22.

The thicker the resist mask 13 is, the deeper the trench 20 can be formed. When the thickness of the resist mask 13 is insufficient for the depth of the trench 20 to be desirably formed, the following mask may be used instead of the resist mask 13. In other words, by depositing an oxide film using TEOS on the upper surface of the source region 4 and the base region 3, and using this oxide film as a mask for dry etching, a deeper trench 20 can be formed.

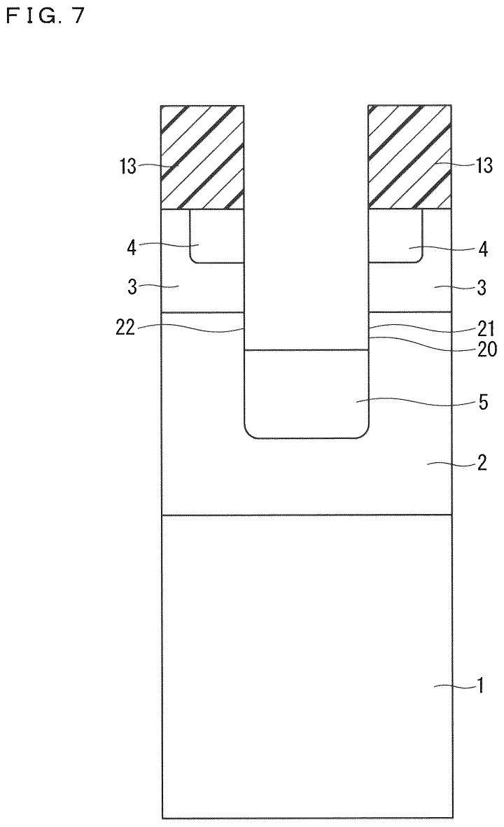

Next, implanting impurities such as boron (B) or aluminum (Al) into the bottom of the trench 20 forms the p-type bottom base region 5 as illustrated in FIG. 7 (Step S5).

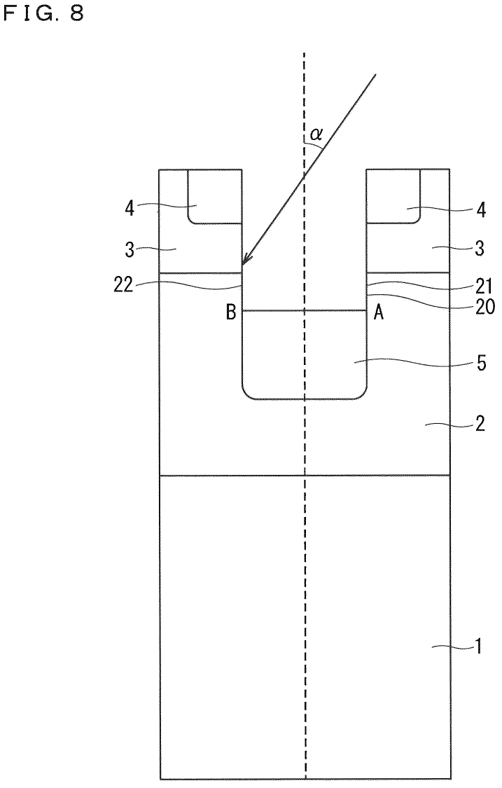

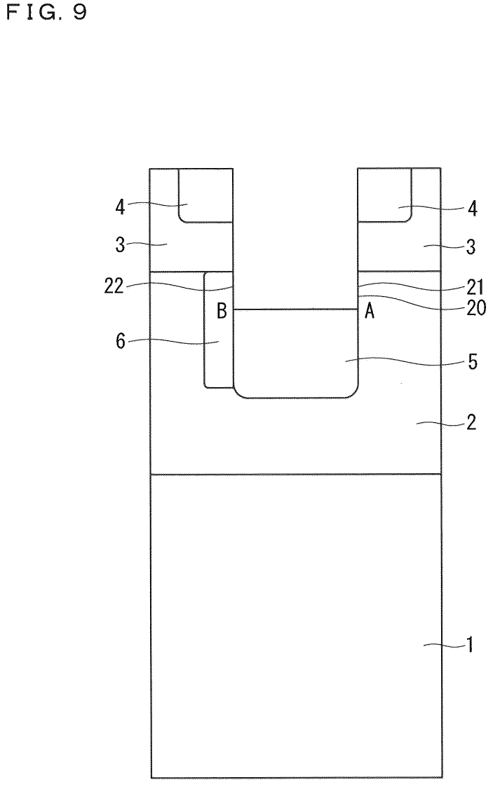

Next, after the resist mask 13 is removed, ions are implanted inside the trench 20 in a slanting direction, that is, in a direction inclined an angle α toward the second sidewall 22 with respect to a depth direction of the trench 20 as illustrated in FIG. 8. This forms the p-type sidewall base region 6 in a part of the drift layer 2 which is in contact with the second sidewall 22 of the trench 20 as illustrated in FIG. 9 (Step S6). Examples of the p-type impurities for forming the sidewall base region 6 include boron (B) and aluminum (Al).

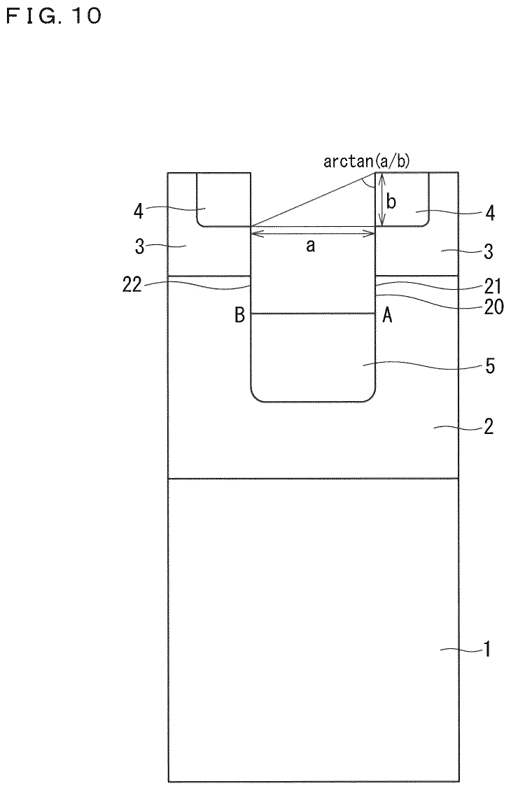

A direction of implanting ions for forming the p-type sidewall base region 6 is as follows. As illustrated in FIG. 10, assuming that “a” denotes a width of the trench 20 and “b” denotes a thickness of the source region 4, an angle α at which ions are implanted in the depth direction of the trench 20 satisfies 0°<α. Furthermore, 0°<α<arctan(a/b) is desired. This is because arctan(a/b)≤α significantly increases the influence of implanting ions for forming the sidewall base region 6 on the shape or the concentration of the source region 4.

As illustrated in FIG. 9, “A” denotes a contacting edge of the upper surface of the bottom base region 5 with the first sidewall 21, and “B” denotes a contacting edge of the upper surface of the bottom base region 5 with the second sidewall 22. Implanting ions under a condition on the angle α described above increases the p-type ion concentration in the bottom base region 5 gradually from “A” to “B”.

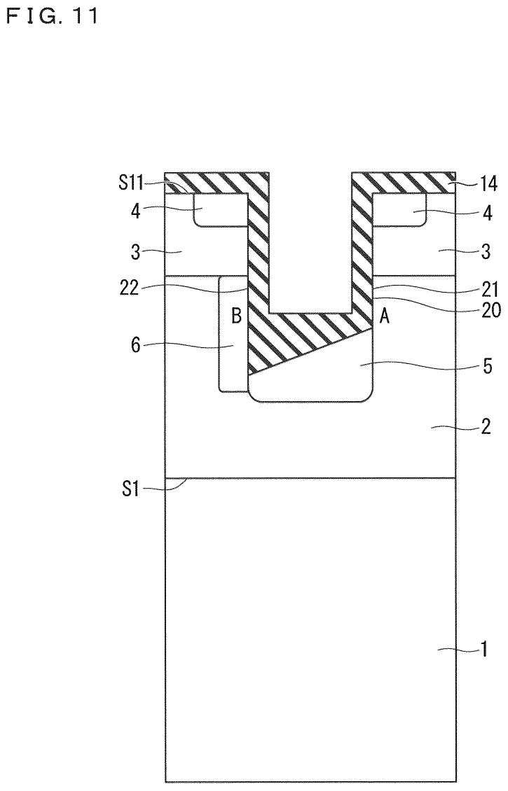

Next, an oxide film 14 is formed inside the trench 20 and on the first main surface S11 by a thermal oxidation method (Step S7). This removes plasma damages in forming the trench 20, and the upper surface of the bottom base region 5 has an inclination with respect to the first main surface S1 of the SiC substrate 1 as illustrated in FIG. 11.

The more the oxidation amount is, the more plasma damages are removed. However, an impurity layer formed in the drift layer 2 decreases. The Inventors herein confirmed by measuring a leakage current between the gate electrode 8 and the source electrode 10 that plasma damages are sufficiently removed when the thermal oxidation amount in the SiC drift layer 2 is 20 nm or larger and 80 nm or smaller, preferably 30 nm or larger and 70 nm or smaller.

When an ion concentration is high, a density of a portion where atoms are missed from a portion where atoms should originally exist, which is referred to as vacancies in a semiconductor, increases. A region with denser vacancies is susceptible to oxidation. Thus, an oxidation amount subjected to thermal oxidation increases as a region has a higher ion concentration. As a result, the oxide film 14 is thicker on the B side, and is thinner on the A side. In other words, the upper surface of the bottom base region 5 is inclined.

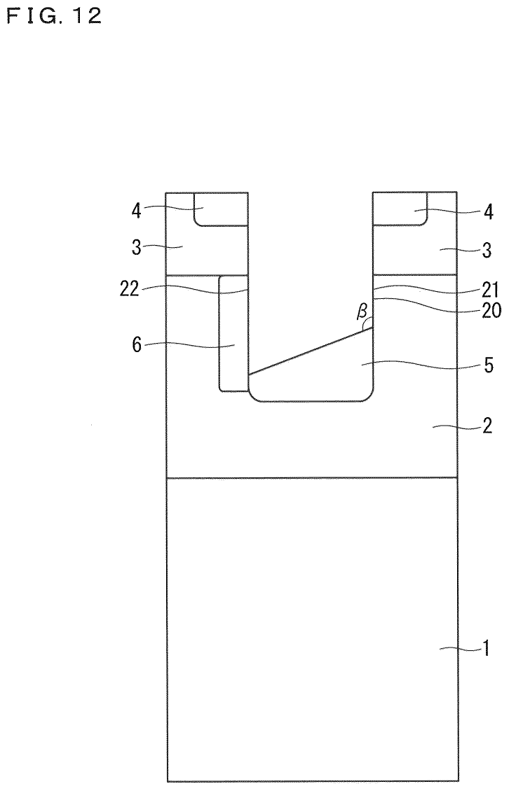

Then, removing the oxide film 14 inclines the bottom of the trench 20 according to the shape of the upper surface of the bottom base region 5 (Step S8). In other words, the bottom of the trench 20 has a slope in a width direction of the trench 20. FIG. 12 illustrates this state. As a slope of the ion concentration between A and B of the bottom base region 5 before a thermal oxidation process in FIG. 9 is larger, a slope of the bottom of the trench 20 after the thermal oxidation process in FIG. 12 is larger.

The first angle β that is an angle of the bottom of the trench 20 with respect to the first sidewall 21 is controlled by the angle α at which ions are implanted when the sidewall base region 6 is formed and the concentration of the ion implantation.

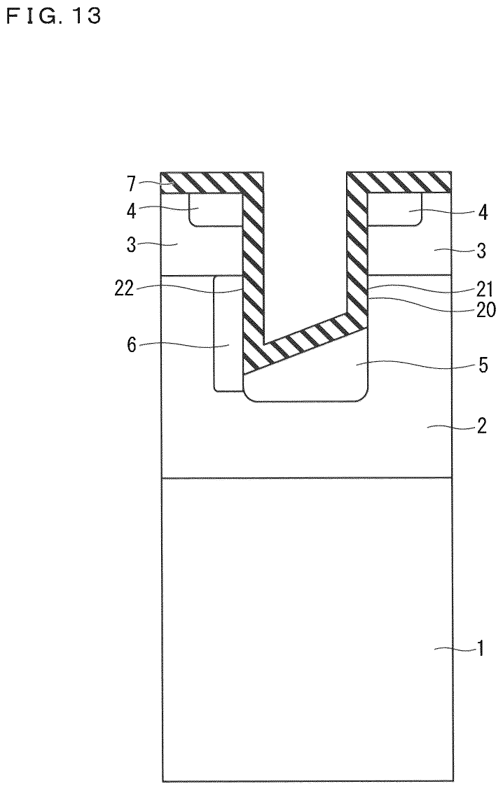

Next, as illustrated in FIG. 13, the gate insulating film 7 is formed inside the trench 20 and on the source region 4 and the base region 3, using a deposition method such as chemical vapor deposition (Step S9). Here, the gate insulating film 7 must not be formed by thermal oxidation. This is because forming the gate insulating film 7 by thermal oxidation changes the first angle β at the bottom of the trench 20.

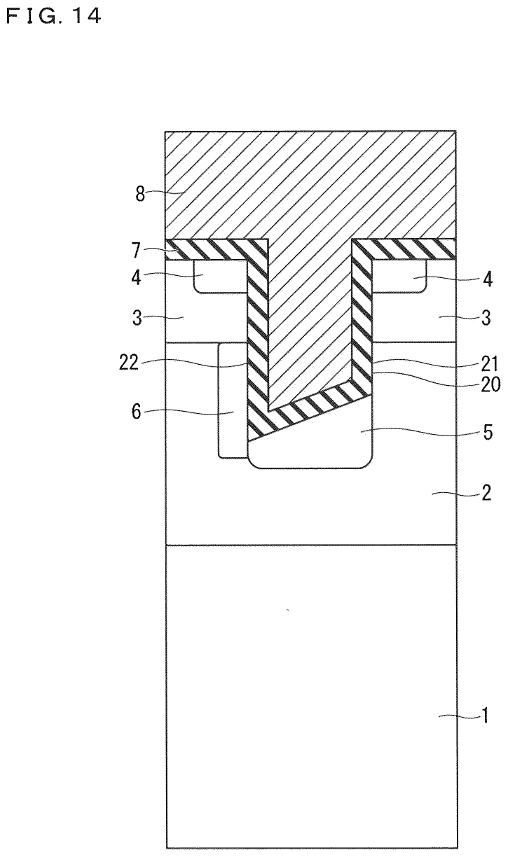

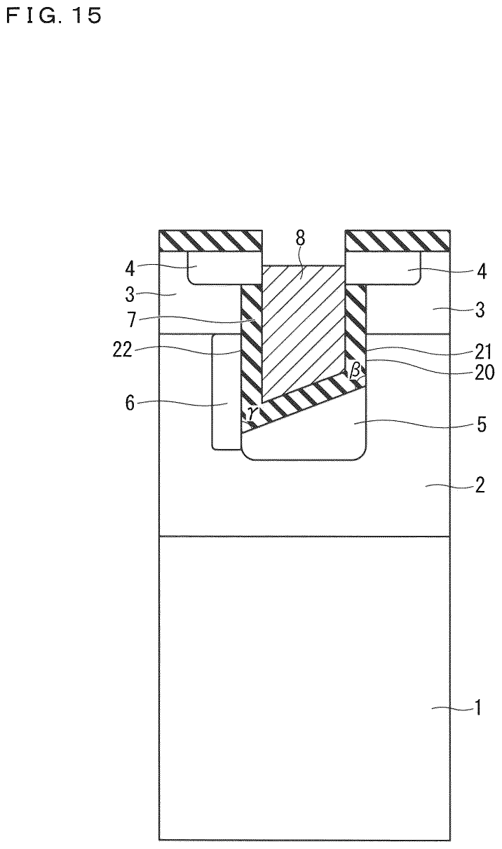

Next, as illustrated in FIG. 14, the gate electrode 8 is deposited to fill the trench 20 on the gate insulating film 7. Then, as illustrated in FIG. 15, the gate electrode 8 is patterned by removing a redundant portion of the gate electrode 8 outside the trench 20. Highly anisotropic etching such as plasma etching can remove only the portion of the gate electrode 8 outside the trench 20. This forms the gate electrode 8 inside the trench 20 (Step S10).

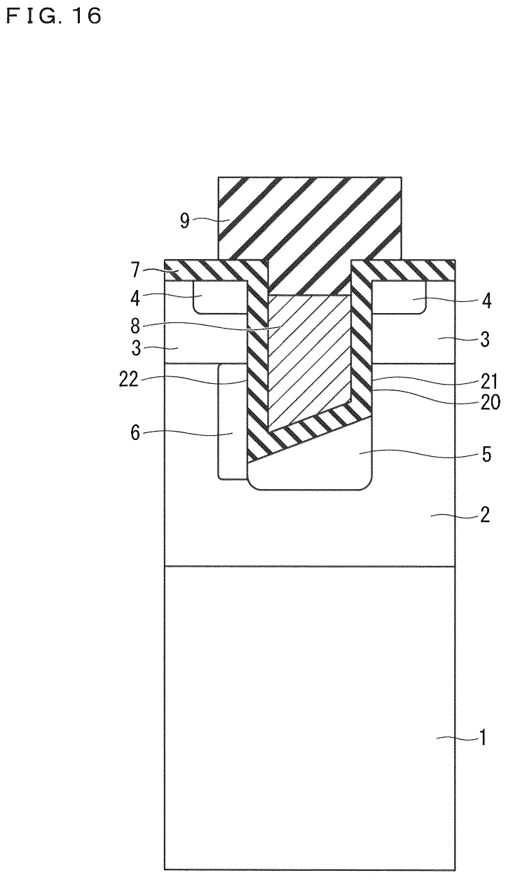

Next, the interlayer insulating film 9 is deposited on the gate electrode 8 and the gate insulating film 7 by chemical vapor deposition (CVD). Then, the interlayer insulating film 9 is patterned by photolithography and an etching process to form the interlayer insulating film 9 on the gate electrode 8 as illustrated in FIG. 16 (Step S11). Introducing impurities such as boron (B) or phosphorus (P) into the interlayer insulating film 9 can round the corners of the interlayer insulating film 9. A material of the interlayer insulating film 9 is, for example, silicon nitride (SiₓN_{y}) or silicon oxide (SiO₂). The thickness of the interlayer insulating film 9 is preferably 0.5 μm or more and 2.0 μm or less.

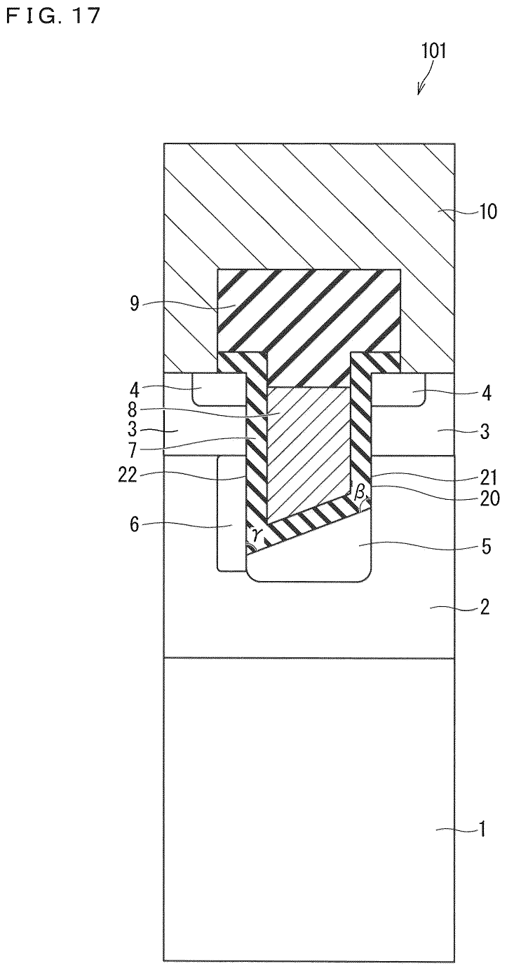

Then, the source electrode 10 is formed as illustrated in FIG. 17 (Step S12). A material of the source electrode 10 is, for example, aluminum, an aluminum alloy of aluminum and silicon, an aluminum alloy of aluminum and copper, or nickel. In addition to the aforementioned material, a barrier metal made of titanium or a titanium compound such as or titanium nitride (TiN) may be appropriately used.

Then, machining the second main surface S2 of the SiC substrate 1 using a grinding wheel as necessary makes the SiC substrate 1 thinner (Step S13).

Then, depositing a nickel film of approximately 600 nm on the second main surface S2 of the SiC substrate 1 by, for example, sputtering forms the drain electrode 11 (Step S14). This results in the SiC-MOSFET 101 in FIG. 1. When the front most surface of the nickel film is oxidized, the wettability of the nickel film with a solder alloy is worsened, and a bonding state in bonding chips is worsened. Thus, a metal that is less reactive to an outside such as gold or silver may be formed on the front surface of the nickel film as a protective film, and a laminated film of the nickel film and, for example, gold or silver may be used as the drain electrode 11.

### A-3. Advantages

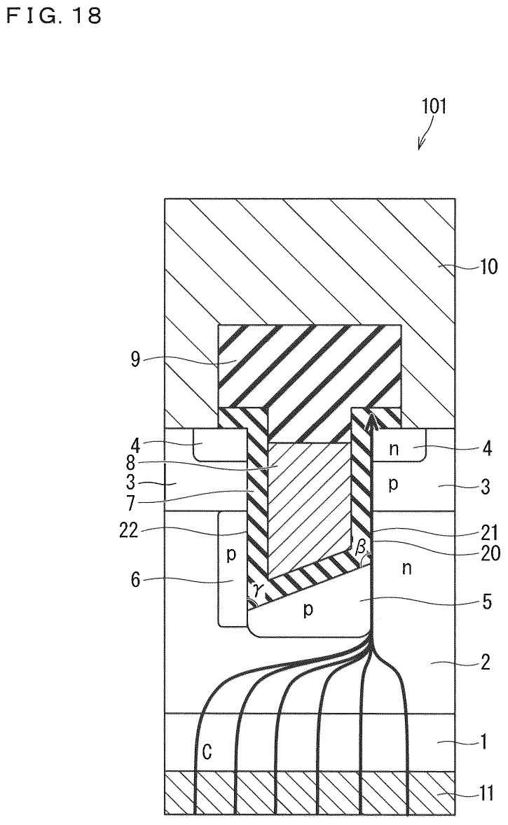

FIG. 18 illustrates current paths in conducting a current through the SiC-MOSFET 101. Solid lines C indicate the current paths when a voltage higher than or equal to a threshold voltage as a voltage measure that allows a current to pass through a semiconductor is applied to the gate electrode 8 to make a potential of the source electrode 10 higher than that of the drain electrode 11. The current flowing through the entirety of an electrode surface of the drain electrode 11 concentrates only on the first sidewall 21 side at which the sidewall base region 6 does not exist in the sidewall of the trench 20. This is because in the second sidewall 22 of the trench 20, an n-type MOS including the drift layer 2, the base region 3, and the source region 4 is not formed due to the existence of the sidewall base region 6, and no current path is formed even with application of the voltage higher than or equal to the threshold voltage to the gate electrode 8. In the first sidewall 21 of the trench 20, the n-type MOS including the drift layer 2, the base region 3, and the source region 4 is formed, and the n-type MOS enters an ON state and a current flows with application of the voltage higher than or equal to the threshold voltage to the gate electrode 8.

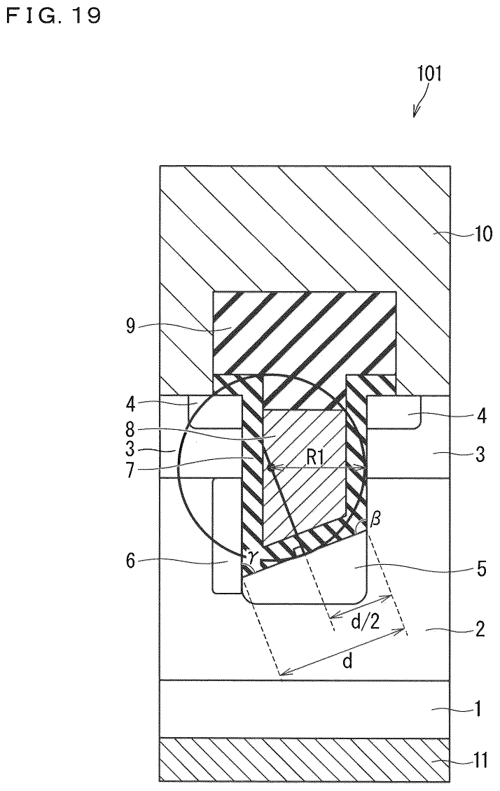

The reason why the electric field at the end of the bottom of the trench 20 is relaxed when the first angle β is larger than the second angle γ at the bottom of the trench 20 will be described. The electric field at the end of the bottom of the trench 20 can be approximated to the electric field of a circular electrode. As illustrated in FIG. 19, a circular electrode with a radius R1 is considered. In the circular electrode, a perpendicular bisector of the bottom of the trench 20 passes through its center, and the circular electrode is in contact with the bottom of the trench 20 and the first sidewall 21. Assuming that V1 denotes a potential difference between the source electrode 10 and the drain electrode 11, an electric field E1 to be applied to an end of the bottom of the trench 20 which is in contact with the first sidewall 21 is proportional to V1/R1 according to Gauss' law. In other words, as R1 is larger, E1 becomes smaller. Furthermore, as the first angle β is larger, R1 is larger and E1 is smaller according to R1/(d/2)=tan(β/2).

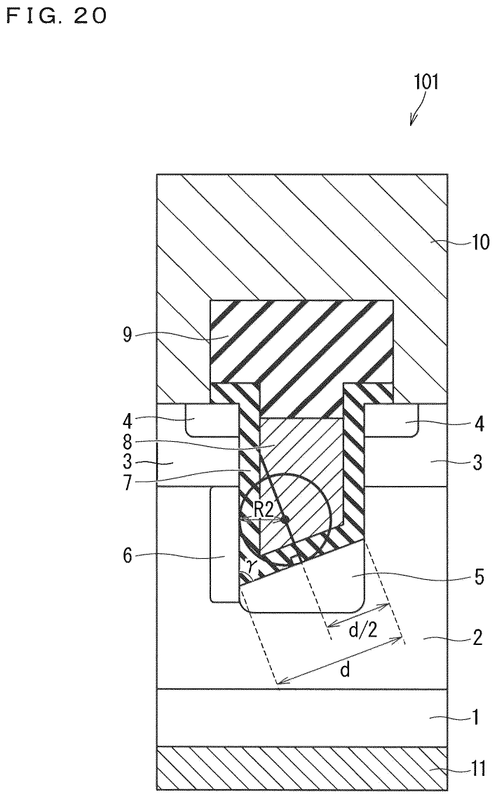

Next, as illustrated in FIG. 20, a circular electrode with a radius R2 is considered. In the circular electrode, a perpendicular bisector of the bottom of the trench 20 passes through its center, and the circular electrode is in contact with the bottom of the trench 20 and the second sidewall 22. An electric field E2 to be applied to the corner at the second angle γ in the bottom of the trench 20 is proportional to V1/R2 according to Gauss' law. As R2 is larger, E2 is smaller. Furthermore, R2/(d/2)=tan(γ/2) holds. Thus, when γ<β, R2<R1 and further E2<E1 hold. In other words, the electric field E1 at the bottom end of the trench 20 which is in contact with the first sidewall 21 functioning as current paths can be smaller than the electric field E2 at the bottom end of the trench 20 which is in contact with the second sidewall 22 not functioning as current paths. This suppresses simultaneous concentration of an electric field and a current at the bottom end of the trench 20, thereby preventing chip destruction.

The SiC-MOSFET 101 according to Embodiment 1 includes the SiC substrate 1, the drift layer 2 of the first conductivity type, the base region 3 of the second conductivity type, the source region 4 of the first conductivity type, the trench 20, the bottom base region 5 of the second conductivity type, the sidewall base region 6 of the second conductivity type, the gate electrode 8, the source electrode 10, and the drain electrode 11. The drift layer 2 is formed on the first main surface S1 of the SiC substrate 1. The base region 3 is formed in the surface layer of the drift layer 2. The source region 4 is partially formed in the surface layer of the base region 3. The trench 20 penetrates the source region 4 and the base region 3 from the surface of the source region 4 to reach the interior of the drift layer 2, and includes the first sidewall 21 and the second sidewall 22 which face each other. The bottom base region 5 is formed in a part of the drift layer 2 which is in contact with the bottom of the trench 20. The sidewall base region 6 is formed in a part of the drift layer 2 which is in contact with the second sidewall 22 of the trench 20. The gate electrode 8 is formed inside the trench 20 through the gate insulating film 7. The source electrode 10 is in contact with the source region 4. The drain electrode 11 is formed on the second main surface S2 of the SiC substrate 1. The angle β between the bottom of the trench 20 and the first sidewall 21 is larger than the second angle γ between the bottom of the trench 20 and the second sidewall 22.

A method of manufacturing the SiC-MOSFET 101 according to Embodiment 1 includes: (a) forming the drift layer 2 of the first conductivity type on the first main surface S1 of the SiC substrate 1; (b) forming the base region 3 of the second conductivity type in a surface layer of the drift layer 2; (c) forming the source region 4 that is an impurity region of the first conductivity type in a part of a surface layer of the base region 3; (d) forming the trench 20 that penetrates the source region 4 from a surface of the source region 4 to reach an interior of the drift layer 2, the trench 20 including the first sidewall 21 and the second sidewall 22 which face each other; (e) forming the bottom base region 5 of the second conductivity type in a part of the drift layer 2, the part being in contact with the bottom of the trench 20; (f) after the step (e), implanting ions in a direction inclined toward the second sidewall 22 with respect to a depth direction of the trench 20 to form the sidewall base region 6 of the second conductivity type in a region of the drift layer 2, and decreasing an impurity concentration of the second conductivity type on an upper surface of the bottom base region 5 from the second sidewall 22 toward the first sidewall 21, the region being in contact with the second sidewall 22; (g) forming a thermal oxide film at the bottom of the trench 20 by a thermal oxidation process, the thermal oxide film being thicker from the first sidewall 21 toward the second sidewall 22; (h) forming the gate insulating film 7 in the trench 20 after the thermal oxide film is removed; (i) forming the gate electrode 8 inside the trench 20 through the gate insulating film 7; (j) forming the source electrode 10 in contact with the source region 4; and (k) forming the drain electrode 11 on the second main surface S2 that is a main surface opposite to the first main surface S1 of the SiC substrate 1. This makes the angle β between the bottom of the trench 20 and the first sidewall 21 larger than the second angle γ between the bottom of the trench 20 and the second sidewall 22. Then, the electric field E1 at the end of the bottom of the trench 20 which is in contact with the first sidewall 21 functioning as current paths becomes smaller than the electric field E2 at the end of the bottom of the trench 20 which is in contact with the second sidewall 22 not functioning as current paths. This consequently suppresses simultaneous concentration of an electric field and a current at the bottom end of the trench 20, thereby preventing chip destruction.

### B. Embodiment 2

### B-1. Structure

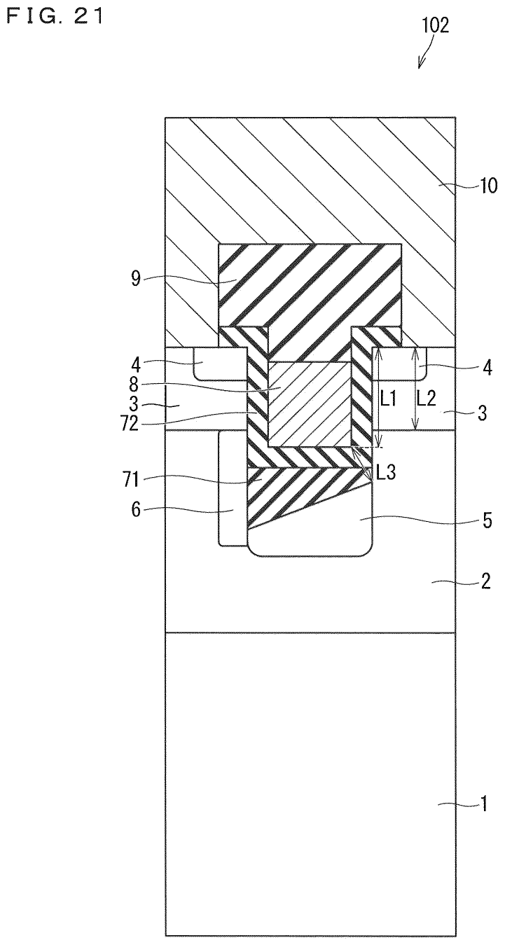

FIG. 21 is a cross-sectional view of a SiC-MOSFET 102 that is a power semiconductor device according to Embodiment 2.

The SiC-MOSFET 102 differs from the SiC-MOSFET 101 according to Embodiment 1 only by a two-layer structure of a first gate insulating film 71 and a second gate insulating film 72 as the gate insulating film inside the trench 20.

The first gate insulating film 71 is formed at the bottom of the trench 20 in contact with the bottom base region 5. An upper surface of the first gate insulating film 71 is located below a lower surface of the base region 3. The second gate insulating film 72 is formed on the first gate insulating film 71 and in the sidewall of the trench 20, and is not in contact with the bottom base region 5. The gate electrode 8 is formed in the trench 20 through the second gate insulating film 72.

### B-2. Manufacturing Method

Next, a method of manufacturing the SiC-MOSFET 102 will be described. The method of manufacturing the SiC-MOSFET 102 differs from the method of manufacturing the SiC-MOSFET 101 according to Embodiment 1 only by a step of forming a gate insulating film (Step S9 in FIG. 2).

First, Steps S1 to S8 in FIG. 2 are performed to form the structure illustrated in FIG. 12.

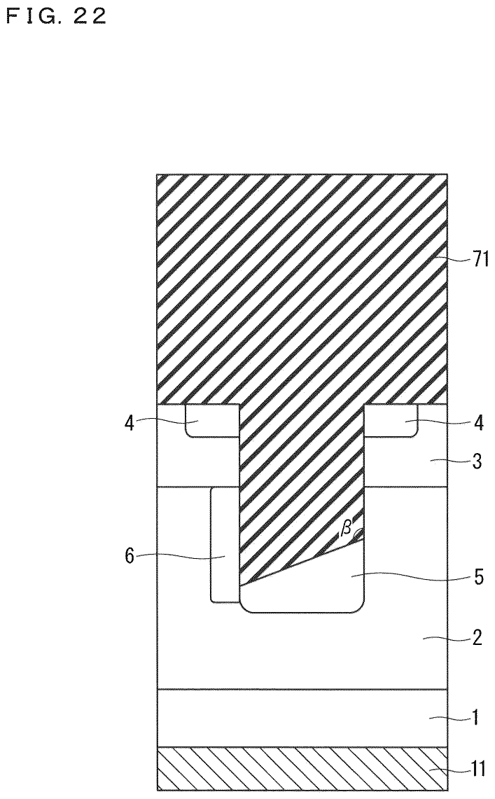

Then, the first gate insulating film 71 is formed inside the trench 20 and on the first main surface S11 by the deposition method such as chemical vapor deposition as illustrated in FIG. 22. The first gate insulating film 71 must not be formed by thermal oxidation. This is because formation of the first gate insulating film 71 by thermal oxidation oxidizes portions of the bottom of the trench 20 with different film thicknesses due to differences in ion concentration between the portions of the bottom of the trench 20, and changes the first angle β at the bottom of the trench 20 as described in Embodiment 1.

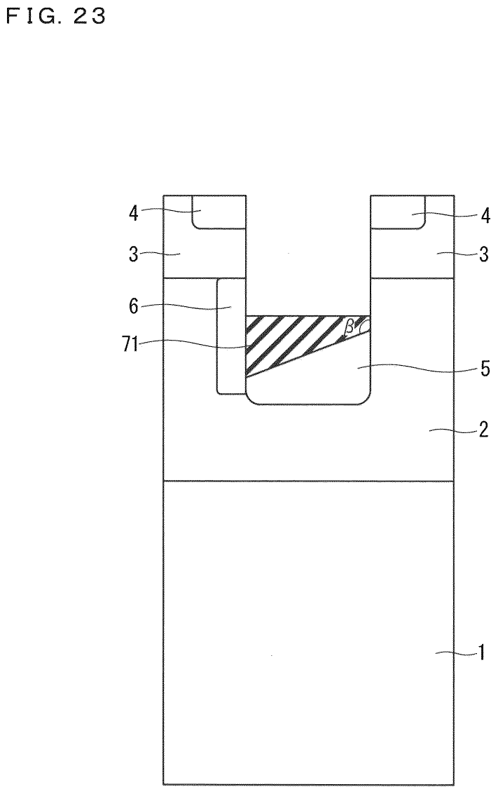

Next, the first gate insulating film 71 is etched back by anisotropic etching to retain the portion in contact with the bottom base region 5 and remove the other portions. Here, the upper surface of the first gate insulating film 71 is located below the base region 3 as illustrated in FIG. 23.

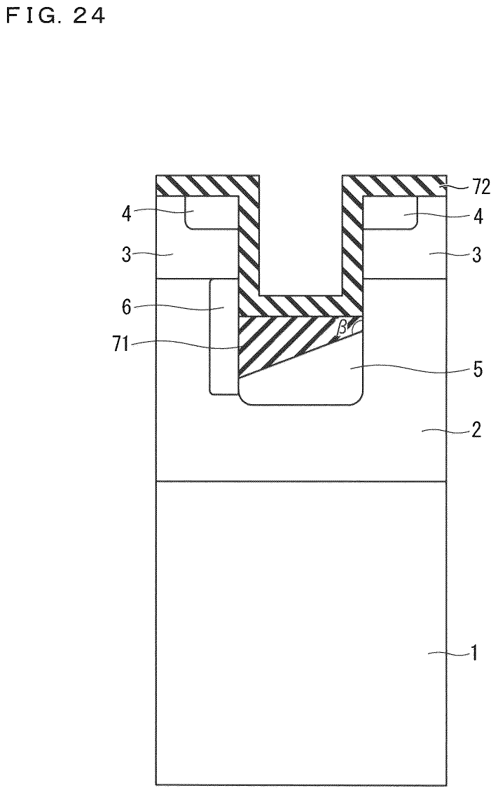

Then, the second gate insulating film 72 is formed on the first gate insulating film 71 and in the sidewall of the trench 20 by the deposition method such as chemical vapor deposition as illustrated in FIG. 24.

Then, the processes from Steps S10 to S14 in FIG. 2 result in the SiC-MOSFET 102 in FIG. 21.

Assuming that L1 denotes the depth of the gate electrode 8 and L2 denotes the depth of the base region 3, L2<L1 needs to be satisfied. This is because when L1<L2, application of a voltage higher than or equal to a threshold voltage to the gate electrode 8 does not invert a part of the base region 3 in the vicinity of the second gate insulating film 72 in the sidewall of the trench 20 so that the part remains in p-type and fails to function as a channel.

### B-3. Advantages

The SiC-MOSFET 102 according to Embodiment 2 includes the first gate insulating film 71 filled in the trench 20 up to a height below the lower surface of the base region 3, and the second gate insulating film 72 formed after the first gate insulating film 71 and covering the sidewall of the trench 20 above the first gate insulating film 71. This can increase a distance L3 between the end of the bottom of the trench 20 which is in contact with the first sidewall 21 and the gate electrode 8 in the SiC-MOSFET 102 more than that in the SiC-MOSFET 101, that is, thicken the gate insulating films between the end and the gate electrode 8. This suppresses the dielectric breakdown of the gate insulating films.

A method of manufacturing the SiC-MOSFET 102 according to Embodiment 2 includes the steps of: filling the trench 20 with the first gate insulating film 71; etching back the first gate insulating film 71 such that an upper surface of the first gate insulating film 71 is located below a lower surface of the base region 3; and then forming the second gate insulating film 72 on the first gate insulating film 71 and in a sidewall of the trench 20. This can increase the distance L3 between the end of the bottom of the trench 20 which is in contact with the first sidewall 21 and the gate electrode 8 in the SiC-MOSFET 102 more than that in the SiC-MOSFET 101, that is, thicken the gate insulating films between the end and the gate electrode 8. This suppresses the dielectric breakdown of the gate insulating films.

### C. Embodiment 3

### C-1. Structure

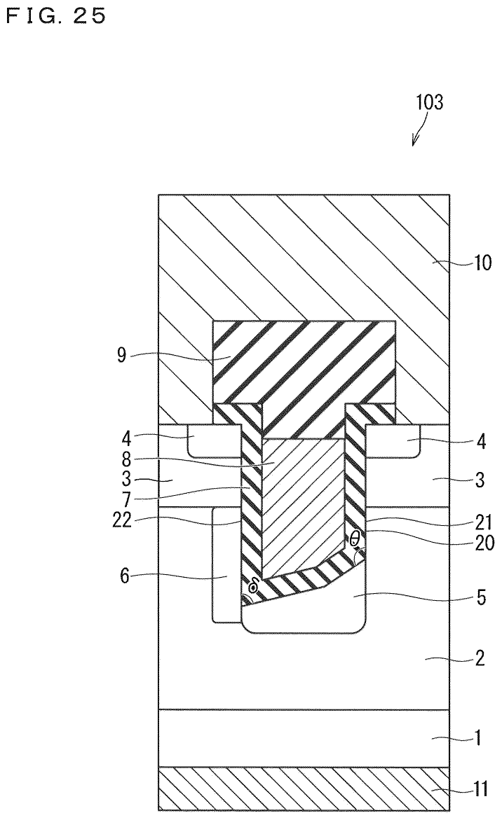

FIG. 25 is a cross-sectional view of a SiC-MOSFET 103 that is a power semiconductor device according to Embodiment 3. The SiC-MOSFET 103 differs from the SiC-MOSFET 101 according to Embodiment 1 only in that the bottom of the trench 20, that is, the upper surface of the bottom base region 5 comprises two surfaces with different slopes. The gate insulating film 7 of the SiC-MOSFET 103 may have the two-layer structure of the gate insulating films described in Embodiment 2.

### C-2. Manufacturing Method

Next, a method of manufacturing the SiC-MOSFET 103 will be described. The method of manufacturing the SiC-MOSFET 103 differs from the method of manufacturing the SiC-MOSFET 101 according to Embodiment 1 only by a step of forming the sidewall base region 6 (Step S6 in FIG. 2).

First, Steps S1 to S5 in FIG. 2 are performed to form the structure illustrated in FIG. 7.

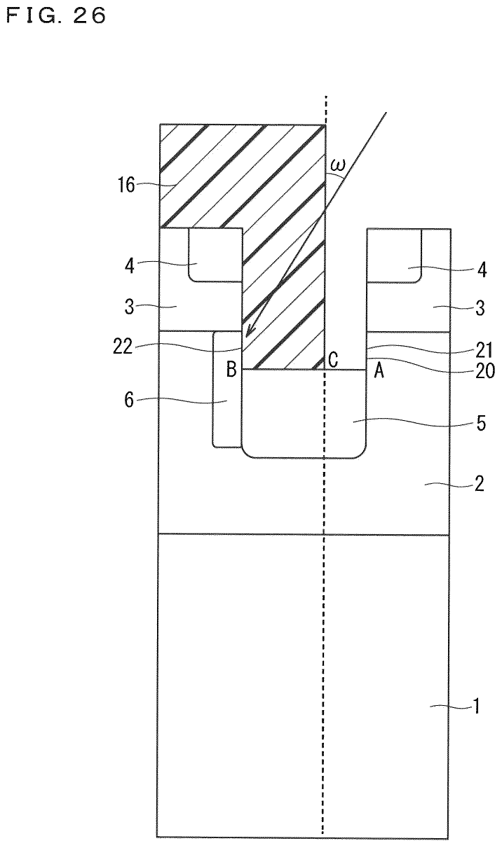

Next, a first resist mask 16 covering a portion (B-C) of the bottom base region 5 closer to the second sidewall 22 and a portion of the first main surface S11 adjacent to the second sidewall 22 is formed as illustrated in FIG. 26. Then, p-type ions are implanted inside the trench 20 in a slanting direction using the first resist mask 16, similarly to Embodiment 1. Here, a direction of implanting ions is a direction inclined only an angle ω toward the second sidewall 22 with respect to the depth direction of the trench 20.

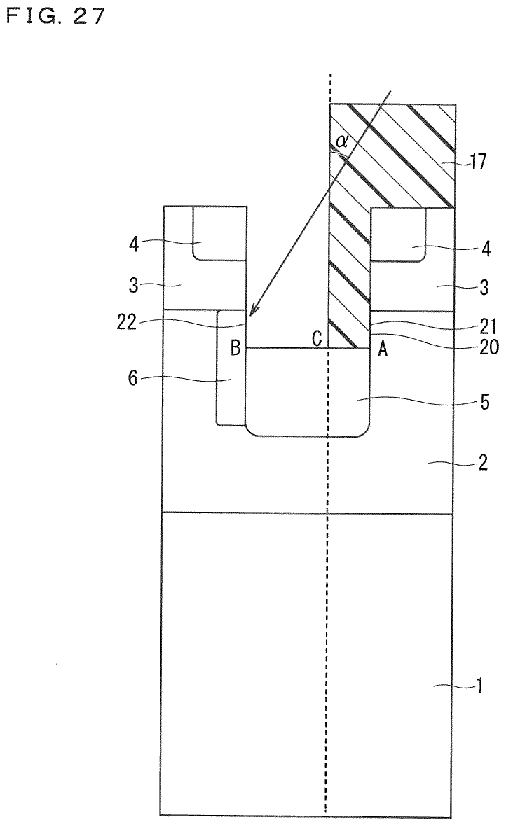

After removing the first resist mask 16, a second resist mask 17 covering a portion (C-A) of the bottom base region 5 closer to the first sidewall 21 and a portion of the first main surface S11 adjacent to the first sidewall 21 is formed as illustrated in FIG. 27. Then, p-type ions are implanted inside the trench 20 in a slanting direction using the second resist mask 17, similarly to Embodiment 1. Here, a direction of implanting ions is a direction inclined only an angle α toward the second sidewall 22 with respect to the depth direction of the trench 20. Here, ω=α need not be satisfied.

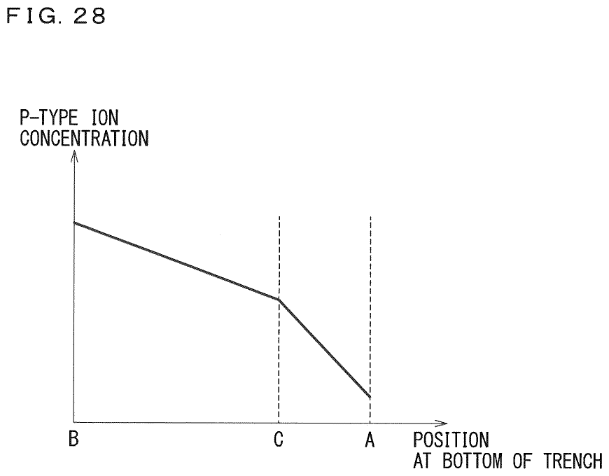

FIG. 28 illustrates a distribution of p-type ion concentration formed between A and B on the upper surface of the bottom base region 5 by implanting ions twice as illustrated in FIGS. 26 and 27. In Embodiment 3, the p-type ion concentration needs to be monotonously lowered from B toward A. Furthermore, a difference in p-type ion concentration between B and C needs to be smaller than a difference in p-type ion concentration between C and A.

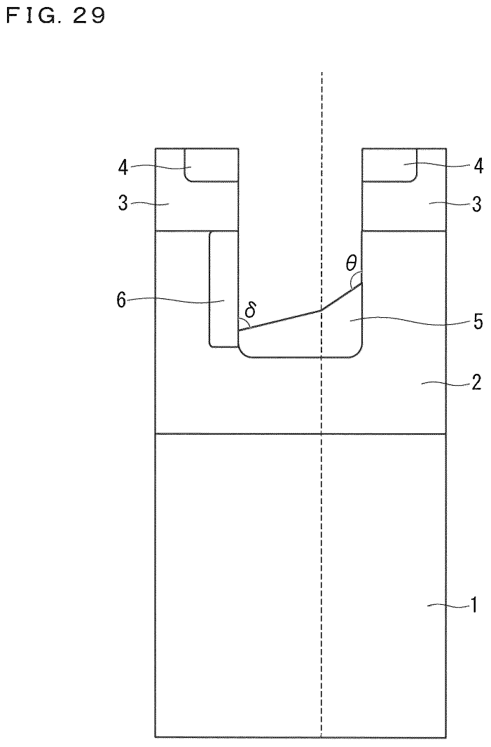

Then, the processes from Steps S7 and S8 in FIG. 2 result in the two surfaces with different slopes at the bottom of the trench 20, that is, on the upper surface of the bottom base region 5 as illustrated in FIG. 29.

Then, the processes from Steps S9 to S14 in FIG. 2 result in the SiC-MOSFET 103 in FIG. 25.

### C-3. Advantages

In the SiC-MOSFET 103, an angle between the bottom of the trench 20 and the first sidewall 21 is defined as a first angle θ, and an angle between the bottom of the trench 20 and the second sidewall 22 is defined as a second angle δ. In the SiC-MOSFET 103, the bottom of the trench 20 comprises the two surfaces with different slopes. Thus, the first angle θ at the bottom of the trench 20 can be larger than the first angle β according to Embodiment 1. Furthermore, when the first angle θ is equal to the first angle β according to Embodiment 1, that is, when θ=β, the second angle δ can be larger than the second angle γ according to Embodiment 1, that is, γ<δ can be satisfied. Thus, when β<θ, the electric field E1 to be applied to the end of the bottom of the trench 20 which is in contact with the first sidewall 21 can be smaller than that according to Embodiment 1. Thus, when θ=β, the electric field E2 to be applied to the end of the bottom of the trench 20 which is in contact with the second sidewall 22 can be smaller than that according to Embodiment 1.

In the method of manufacturing the SiC-MOSFET 103, implanting ions for forming the sidewall base region 6 includes implanting ions for the first time for covering the second sidewall 22 inside the trench 20 using the first resist mask 16, and implanting ions for the second time for covering, using the second resist mask 17, the first sidewall 21 inside the trench 20 which is not covered with the first resist mask 16. Thereby, the bottom of the trench 20 can comprise the two surfaces with different slopes through the subsequent thermal oxidation process.

### D. Embodiment 4

### D-1. Structure

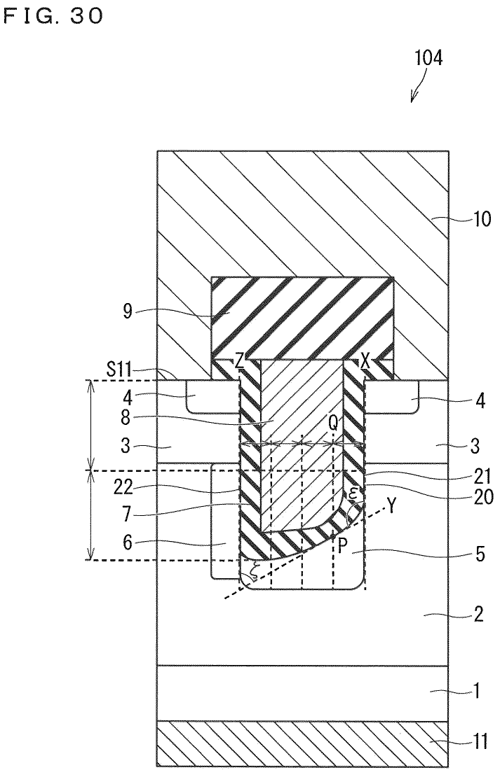

FIG. 30 is a cross-sectional view of a SiC-MOSFET 104 that is a power semiconductor device according to Embodiment 4. The SiC-MOSFET 104 differs from the SiC-MOSFET 101 according to Embodiment 1 only in that the bottom of the trench 20, that is, the upper surface of the bottom base region 5 is a curved-surface.

A tangential line of the gate insulating film 7 at a point in which the first sidewall 21 of the trench 20 is divided into two with respect to the first main surface S11 and the deepest point of the trench 20 is defined as a tangential line X. A tangential line of the gate insulating film 7 at points P in which parting lines Q that equally horizontally divide the trench 20 into four intersects the gate insulating film 7 is defined as a tangential line Y. An angle formed between the tangential line X and the tangential line Y is a third angle ε.

A tangential line of the gate insulating film 7 at a point in which the second sidewall 22 of the trench 20 is vertically divided into two with respect to the surface of the source region 4 and the deepest point of the trench 20 is defined as a tangential line Z. An angle formed between the tangential line Z and the tangential line Y is a fourth angle ζ.

The third angle ε is larger than the fourth angle ζ. Furthermore, the fourth angle ζ is less than 90°.

### D-2. Manufacturing Method

Next, a method of manufacturing the SiC-MOSFET 104 will be described. The method of manufacturing the SiC-MOSFET 104 differs from the method of manufacturing the SiC-MOSFET 101 according to Embodiment 1 only by a step of forming the trench 20 (Step S4 in FIG. 2).

First, Steps S1 to S3 in FIG. 2 are performed to form the structure illustrated in FIG. 6.

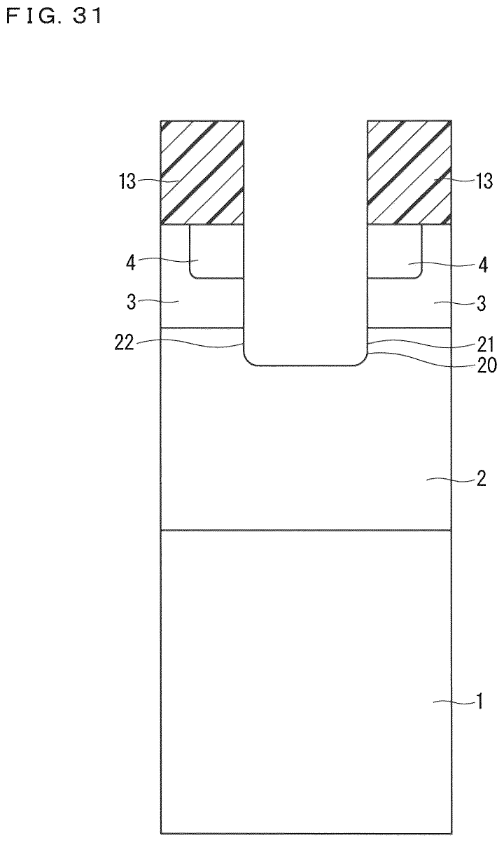

Next, corners at the bottom of the trench 20 are curved by isotropic etching as illustrated in FIG. 31.

Then, the processes from Steps S5 to S14 in FIG. 2 form a structure including a curved surface at the bottom of the trench 20, that is, on the bottom base region 5, and result in the SiC-MOSFET 104 in FIG. 30.

### D-3. Advantages

The bottom of the trench 20 is curved in the SiC-MOSFET 104. Furthermore, the third angle ε between the first sidewall 21 and the tangential line Y of the gate insulating film 7 at a point in which the bottom of the trench 20 intersects the parting line the closest to the first sidewall among the parting lines Q that equally divide the trench 20 into four in the horizontal direction is larger than the fourth angle ζ between the tangential line Y of the gate insulating film 7 and the second sidewall 22. Furthermore, the fourth angle ζ is less than 90°. In the SiC-MOSFET 104 with such a structure, since the bottom of the trench 20 is a curved surface, the concentration of electric fields to be applied to ends of the bottom of the trench 20 is dispersed. This suppresses simultaneous concentration of an electric field and a current at the bottom end of the trench 20, thereby preventing chip destruction.

### E. Embodiment 5

Embodiment 5 will describe a power conversion device to which the power semiconductor devices according to Embodiments 1 to 4 are applied. Although application of the power semiconductor devices according to Embodiments 1 to 4 is not limited to specific power conversion devices, Embodiment 5 will describe application of the power semiconductor devices according to Embodiments 1 to 4 to a three-phase inverter.

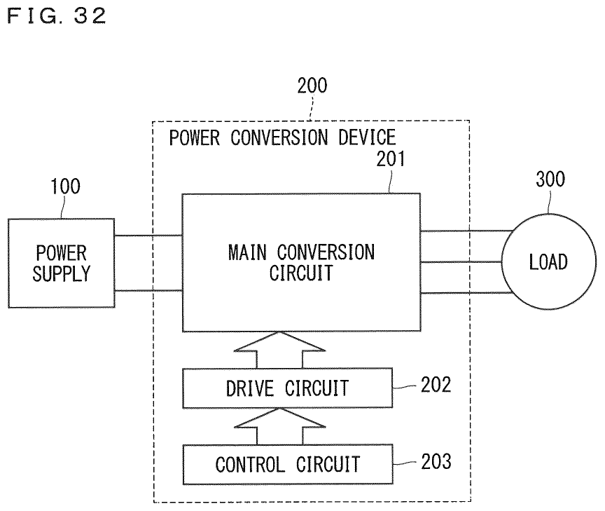

FIG. 32 is a block diagram illustrating a configuration of a power conversion system to which the power conversion device according to Embodiment 5 is applied.

The power conversion system illustrated in FIG. 32 includes a power supply 100, a power conversion device 200, and a load 300. The power supply 100, which is a DC power supply, supplies a DC power to the power conversion device 200. The power supply 100 may include various components such as a DC system, a solar battery, and a rechargeable battery, a rectifying circuit connected to an AC system, and an AC/DC converter. The power supply 100 may include a DC/DC converter which converts the DC power output from a DC system into a predefined power.

The power conversion device 200 is a three-phase inverter connected between the power supply 100 and the load 300, and converts the DC power supplied from the power supply 100 into the AC power to supply the AC power to the load 300. As illustrated in FIG. 32, the power conversion device 200 includes a main conversion circuit 201 that converts the DC power to output the AC power, a drive circuit 202 that outputs a driving signal for driving each switching device in the main conversion circuit 201, and a control circuit 203 that outputs, to the drive circuit 202, a control signal for controlling the drive circuit 202.

The load 300 is a three-phase electrical motor driven by the AC power supplied from the power conversion device 200. The load 300 is not limited to specific use but is an electrical motor mounted on various types of electrical devices. Thus, the load 300 is used as an electrical motor for, for example, a hybrid car, an electrical car, a rail vehicle, an elevator, or air-conditioning equipment.

The power conversion device 200 will be described in detail hereinafter. The main conversion circuit 201 includes the switching devices and freewheeling diodes (not illustrated). Switching of the switching devices allows the main conversion circuit 201 to convert the DC power supplied from the power supply 100 into the AC power and supply the AC power to the load 300. The specific circuit configuration of the main conversion circuit 201 is of various types. The main conversion circuit 201 according to Embodiment 5 is a three-phase full-bridge circuit having two levels, and includes the six switching devices and the six freewheeling diodes anti-parallel connected to the respective switching devices. The power semiconductor device according to any one of Embodiments 1 to 4 is applied to each of the switching devices in the main conversion circuit 201. The six switching devices form pairs of upper and lower arms in each pair of which the two switching devices are serially connected to each other. The pairs of upper and lower arms form the respective phases (U-phase, V-phase, and W-phase) of a full-bridge circuit. Output terminals of the respective pairs of upper and lower arms, i.e., three output terminals of the main conversion circuit 201 are connected to the load 300.

The drive circuit 202 generates driving signals for driving the switching devices of the main conversion circuit 201, and provides the driving signals to control electrodes of the switching devices of the main conversion circuit 201. Specifically, the drive circuit 202 outputs the driving signal for switching each of the switching devices to an ON state and the driving signal for switching the switching device to an OFF state, to a control electrode of the switching device in accordance with the control signal from the control circuit 203 to be described later. When the switching device is kept in the ON state, the driving signal is a voltage signal (ON signal) higher than or equal to a threshold voltage of the switching device. When the switching device is kept in the OFF state, the driving signal is a voltage signal (OFF signal) lower than the threshold voltage of the switching device.

The control circuit 203 controls the switching devices of the main conversion circuit 201 to supply a desired power to the load 300. Specifically, the control circuit 203 calculates a time (ON time) when each of the switching devices of the main conversion circuit 201 needs to enter the ON state, based on the power which needs to be supplied to the load 300. For example, the control circuit 203 can control the main conversion circuit 201 by PWM control for modulating the ON time of the switching devices in accordance with the voltage which needs to be output. Then, the control circuit 203 outputs a control instruction (a control signal) to the drive circuit 202 so that the drive circuit 202 outputs the ON signal to the switching device which needs to enter the ON state and outputs the OFF signal to the switching device which needs to enter the OFF state at each time. The drive circuit 202 outputs the ON signal or the OFF signal as the driving signal to the control electrode of each of the switching devices in accordance with this control signal.

In the power conversion device according to Embodiment 5, the power semiconductor devices according to Embodiments 1 to 4 are applied to the switching devices in the main conversion circuit 201. Thus, destruction of chips of the switching devices can be suppressed.

While Embodiment 5 describes the example of applying the power semiconductor devices according to Embodiments 1 to 4 to the three-phase inverter having the two levels, application of the power semiconductor devices according to Embodiments 1 to 4 is not limited thereto, but the power semiconductor devices are applicable to various power conversion devices. While the power conversion device according to Embodiment 5 is the power conversion device having the two levels, the power conversion device may have three or multiple levels. The power semiconductor devices according to Embodiments 1 to 4 may be applied to a single-phase inverter when the power is supplied to a single-phase load. Furthermore, the power semiconductor devices according to Embodiments 1 to 4 may be applied to a DC/DC converter or an AC/DC converter when the power is supplied to, for example, a DC load.

The load of the power conversion device to which the power semiconductor devices according to Embodiments 1 to 4 are applied is not limited to the electrical motor as described above. The power conversion device can also be used as a power-supply device of, for example, an electrical discharge machine, a laser beam machine, an induction heat cooking device, or a non-contact power feeding system, and can be further used as a power conditioner of, for example, a solar power system or an electricity storage system.

While, for example, preferred embodiments are described above in detail, various modifications and replacements can be added to, for example, Embodiments above without being limited to Embodiments and without departing from claims.

A summary of various aspects of the present disclosure will be hereinafter described as Appendixes.

### Appendix 1

A power semiconductor device, comprising:
a SiC substrate;
a drift layer of a first conductivity type, the drift layer being formed on a first main surface of the SiC substrate;
a base region of a second conductivity type, the base region being formed in a surface layer of the drift layer;
an impurity region of the first conductivity type, the impurity region being partially formed in a surface layer of the base region;
a trench penetrating the impurity region and the base region from a surface of the impurity region to reach an interior of the drift layer, the trench including a first sidewall and a second sidewall which face each other;
a bottom base region of the second conductivity type, the bottom base region being formed in a part of the drift layer, the part being in contact with a bottom of the trench;
a sidewall base region of the second conductivity type, the sidewall base region being formed in a part of the drift layer, the part being in contact with the second sidewall of the trench;
a gate electrode formed inside the trench through a gate insulating film;
a surface electrode in contact with the impurity region; and
a back electrode formed on a second main surface that is a main surface opposite to the first main surface of the SiC substrate,
wherein an angle between the bottom of the trench and the first sidewall is larger than an angle between the bottom of the trench and the second sidewall, and
the angle between the bottom of the trench and the second sidewall is less than 90°.

### Appendix 2

The power semiconductor device according to appendix 1,
wherein the gate insulating film includes:
a first gate insulating film filled in the trench up to a height below a lower surface of the base region; and
a second gate insulating film formed after the first gate insulating film and covering a sidewall of the trench above the first gate insulating film.

### Appendix 3

The power semiconductor device according to appendix 1 or 2,
wherein the bottom of the trench comprises two surfaces with different slopes.

### Appendix 4

The power semiconductor device according to any one of appendixes 1 to 3,
wherein the bottom of the trench is curved,
a third angle that is an angle formed between the first sidewall and a tangential line of the gate insulating film at a point in which the bottom of the trench intersects a parting line closest to the first sidewall among parting lines that equally divide the trench into four in a horizontal direction is larger than a fourth angle that is an angle formed between the tangential line of the gate insulating film and the second sidewall, and
the fourth angle is less than 90°.

### Appendix 5

A power conversion device, comprising:
a main conversion circuit including the power semiconductor device according to any one of appendixes 1 to 4, the main conversion circuit converting an input power to output a resulting power;
a drive circuit outputting, to the power semiconductor device, a driving signal for driving the power semiconductor device; and
a control circuit outputting, to the drive circuit, a control signal for controlling the drive circuit.

### Appendix 6

A method of manufacturing a power semiconductor device, the method comprising the steps of:
(a) forming a drift layer of a first conductivity type on a first main surface of a SiC substrate;
(b) forming a base region of a second conductivity type in a surface layer of the drift layer;
(c) forming an impurity region of the first conductivity type in a part of a surface layer of the base region;
(d) forming a trench that penetrates the impurity region from a surface of the impurity region to reach an interior of the drift layer, the trench including a first sidewall and a second sidewall which face each other;
(e) forming a bottom base region of the second conductivity type in a part of the drift layer, the part being in contact with a bottom of the trench;
(f) after the step (e), implanting ions in a direction inclined toward the second sidewall with respect to a depth direction of the trench to form a sidewall base region of the second conductivity type in a region of the drift layer in contact with the second sidewall, such that an impurity concentration of the second conductivity type increases on an upper surface of the bottom base region from the first sidewall toward the second sidewall;
(g) forming a thermal oxide film at the bottom of the trench by a thermal oxidation process, the thermal oxide film being thicker from the first sidewall toward the second sidewall;
(h) forming a gate insulating film in the trench after the thermal oxide film is removed;
(i) forming a gate electrode inside the trench through the gate insulating film;
(j) forming a surface electrode in contact with the impurity region; and
(k) forming a back electrode on a second main surface that is a main surface opposite to the first main surface of the SiC substrate.

### Appendix 7

The method according to appendix 6,
wherein an angle α in a direction in which ions are implanted with respect to the depth direction of the trench in the step (f) satisfies 0°<α.

### Appendix 8

The method according to appendix 6 or 7,
wherein the gate insulating film includes a first gate insulating film and a second gate insulating film, and
the step (h) includes the steps of:
(h1) filling the trench with the first gate insulating film;
(h2) etching back the first gate insulating film such that an upper surface of the first gate insulating film is located below a lower surface of the base region; and
(h3) forming the second gate insulating film on the first gate insulating film and in a sidewall of the trench after the step (h2).

### Appendix 9

The method according to any one of appendixes 6 to 8,
wherein the implanting in the step (f) includes:
implanting ions for a first time for covering the second sidewall inside the trench using a first resist mask; and
implanting ions for a second time for covering, using a second resist mask, the first sidewall inside the trench which is not covered with the first resist mask.

### EXPLANATION OF REFERENCE SIGNS

1 SiC substrate, 2 drift layer, 3 base region, 4 source region, 5 bottom base region, 6 sidewall base region, 7 gate insulating film, 8 gate electrode, 9 interlayer insulating film, 10 source electrode, 11 drain electrode, 12, 13 resist mask, 14 oxide film, 16 first resist mask, 17 second resist mask, 20 trench, 21 first sidewall, 22 second sidewall, 50 semiconductor substrate, 71 first gate insulating film, 72 second gate insulating film, S1, S11 first main surface, S2, S12 second main surface.

1. A power semiconductor device, comprising:
a SiC substrate;
a drift layer of a first conductivity type, the drift layer being formed on a first main surface of the SiC substrate;
a base region of a second conductivity type, the base region being formed in a surface layer of the drift layer;
an impurity region of the first conductivity type, the impurity region being partially formed in a surface layer of the base region;
a trench penetrating the impurity region and the base region from a surface of the impurity region to reach an interior of the drift layer, the trench including a first sidewall and a second sidewall which face each other;
a bottom base region of the second conductivity type, the bottom base region being formed in a part of the drift layer such that an impurity concentration of the second conductivity type increases from the first sidewall toward the second sidewall, the part being in contact with a bottom of the trench;
a sidewall base region of the second conductivity type, the sidewall base region being formed in a part of the drift layer, the part being in contact with the second sidewall of the trench;
a gate electrode formed inside the trench through a gate insulating film;
a surface electrode in contact with the impurity region; and
a back electrode formed on a second main surface that is a main surface opposite to the first main surface of the SiC substrate,
wherein an angle between the bottom of the trench and the first sidewall is larger than an angle between the bottom of the trench and the second sidewall, and
the angle between the bottom of the trench and the second sidewall is less than 90°.

2. The power semiconductor device according to claim 1,
wherein the gate insulating film includes:
a first gate insulating film filled in the trench up to a height below a lower surface of the base region; and
a second gate insulating film formed after the first gate insulating film and covering a sidewall of the trench above the first gate insulating film.

3. The power semiconductor device according to claim 1,
wherein the bottom of the trench comprises two surfaces with different slopes.

4. The power semiconductor device according to claim 1,
wherein the bottom of the trench is curved,
a third angle that is an angle formed between the first sidewall and a tangential line of the gate insulating film at a point in which the bottom of the trench intersects a parting line closest to the first sidewall among parting lines that equally divide the trench into four in a horizontal direction is larger than a fourth angle that is an angle formed between the tangential line of the gate insulating film and the second sidewall, and
the fourth angle is less than 90°.

5. A power conversion device, comprising:
a main conversion circuit including the power semiconductor device according to claim 1, the main conversion circuit converting an input power to output a resulting power;
a drive circuit outputting, to the power semiconductor device, a driving signal for driving the power semiconductor device; and
a control circuit outputting, to the drive circuit, a control signal for controlling the drive circuit.

6. A method of manufacturing a power semiconductor device, the method comprising the steps of:
(a) forming a drift layer of a first conductivity type on a first main surface of a SiC substrate;
(b) forming a base region of a second conductivity type in a surface layer of the drift layer;
(c) forming an impurity region of the first conductivity type in a part of a surface layer of the base region;
(d) forming a trench that penetrates the impurity region from a surface of the impurity region to reach an interior of the drift layer, the trench including a first sidewall and a second sidewall which face each other;
(e) forming a bottom base region of the second conductivity type in a part of the drift layer, the part being in contact with a bottom of the trench;
(f) after the step (e), implanting ions in a direction inclined toward the second sidewall with respect to a depth direction of the trench to form a sidewall base region of the second conductivity type in a region of the drift layer in contact with the second sidewall, such that an impurity concentration of the second conductivity type increases on an upper surface of the bottom base region from the first sidewall toward the second sidewall;
(g) forming a thermal oxide film at the bottom of the trench by a thermal oxidation process, the thermal oxide film being thicker from the first sidewall toward the second sidewall;
(h) forming a gate insulating film in the trench after the thermal oxide film is removed;
(i) forming a gate electrode inside the trench through the gate insulating film;
(j) forming a surface electrode in contact with the impurity region; and
(k) forming a back electrode on a second main surface that is a main surface opposite to the first main surface of the SIC substrate.

7. The method according to claim 6,
wherein an angle α in a direction in which ions are implanted with respect to the depth direction of the trench in the step (f) satisfies 0°<α.

8. The method according to claim 6,
wherein the gate insulating film includes a first gate insulating film and a second gate insulating film, and
the step (h) includes the steps of:
(h1) filling the trench with the first gate insulating film;
(h2) etching back the first gate insulating film such that an upper surface of the first gate insulating film is located below a lower surface of the base region; and
(h3) forming the second gate insulating film on the first gate insulating film and in a sidewall of the trench after the step (h2).

9. The method according to claim 6,
wherein the implanting in the step (f) includes:
implanting ions for a first time for covering the second sidewall inside the trench using a first resist mask; and
implanting ions for a second time for covering, using a second resist mask, the first sidewall inside the trench which is not covered with the first resist mask.
